(19) United States
(12) Patent Application Publication
(10) Pub. No.: US 2008/0274268 A1
(43) Pub. Date: Nov. 6, 2008

(54) METHOD OF PRODUCING ORGANIC EL DEVICES

(75) Inventor: Shinji OGINO, Hino-City (JP)

Correspondence Address: ROSSI, KIMMS & McDOWELL LLP., 20609 Gordon Park Square, Suite 150, Ashburn, VA, 20147, US

(73) Assignee: Fuji Electric Holdings Co., Ltd., Kawasaki (JP)

(21) Appl. No.: 12/053,847

(22) Filed: Mar. 24, 2008

(30) Foreign Application Priority Data
Mar. 26, 2007 (JP) 2007-079844

(51) Int. Cl. B05D 5/12

(52) U.S. Cl. 427/66

(57) ABSTRACT

A method of producing an organic EL device is provided that realizes excellent color reproducibility in the organic EL device as a result of the excellent transparency of the passivation layer. During formation of a passivation layer by a CVD method in the production of an organic EL device that is provided with the passivation layer, a layer in which the internal stress is compressive stress and a layer in which the internal stress is tensile stress are stacked by modulating a gas pressure while holding a gas composition ratio constant.

### CROSS REFERENCE TO RELATED APPLICATIONS

This application claims priority from Japanese application Serial No. 2007-079844, filed on Mar. 26, 2007.

### BACKGROUND OF THE INVENTION

A. Field of the Invention

The present invention relates to a method of producing organic EL devices and more particularly relates to a method of producing organic EL devices that is capable of increasing the transparency of a passivation layer and is thereby capable of improving the color reproducibility of an organic EL device.

B. Description of the Related Art

Organic EL devices are used in display devices such as organic EL displays and so forth. The following production modes (1) and (2) have heretofore generally been used with organic EL device-based displays that employ a color conversion material-type organic EL device, which are devices in which a layer of color conversion material (also abbreviated hereafter as CCM) is provided on the glass substrate.

(1) Bottom Emission-Type Organic EL Devices

A CCM layer and color filter layer are first formed on a glass substrate. An overcoat layer (also abbreviated hereafter as OCL) is then formed and a passivation layer (also abbreviated hereafter as PL) containing SiN, SiON, SiO₂, or the like is additionally formed. This PL is formed in order to inhibit the production of non-emitting defects, e.g., dark spots (also abbreviated hereafter as DS), dark areas (also abbreviated hereafter as DA), and so forth, due to the diffusion of residual moisture and solvent present in the OCL. A transparent electroconductive film, e.g., indium tin oxide (ITO), indium zinc oxide (IZO), and so forth, is then formed on the passivation layer, an organic layer is subsequently vapor deposited, and a cathode comprising aluminum is thereafter formed to yield the organic EL device.

When an organic EL device produced in this manner is allowed to stand, moisture in the atmosphere reaches the organic layer through defects in the aluminum cathode, creating a risk of DA and/or DS production. A hygroscopic material is therefore enclosed when the cover glass is bonded to the organic EL device using an ultraviolet-curing epoxy resin. This inhibits the infiltration of moisture into the organic layer. The thickness of the cover glass in this production mode generally reaches to about 1 mm.

(2) Top Emission-Type Organic EL Devices

When a display is produced using a top emission-type organic EL device, an electrode-containing organic EL device is first formed on a substrate that is provided with, e.g., thin-film transistors. A passivation layer is then provided on this device, followed by attachment of a substrate on which a CCM and color filter layer are formed. As in the bottom emission example, a cover glass is bonded to the organic EL device using an ultraviolet-curing epoxy resin, and a hygroscopic material is enclosed at this point.

A monolith or a layered structure of silicon oxide, silicon nitride, or silicon oxynitride having a relatively high transmittance in the visible region is used for the passivation layer that is employed in the production of the bottom emission-type organic EL device and top emission-type organic EL device. Alternatively, a layered structure comprising a transparent inorganic film of the above-cited type and an organic resin may also be used for the passivation layer.

Even when the above-described sealing methodology is employed, there is a risk in particular that residual moisture and so forth present in the OCL will infiltrate into the passivation layer. This moisture additionally reaches into the organic layer along pathways created by microdefects that traverse the passivation layer, leading to the formation of point defects, such as dark spots, in the organic layer in a relatively short period of time. Some of these microdefects are due to an opening up and broadening when the internal stress in the passivation layer is tensile stress. In addition, microdefects present only in the interior can traverse the passivation layer as fissures.

The photograph in FIG. 3 shows the results of the observation of the etch pits produced when a silicon nitride layer was formed as a passivation layer on a silicon wafer under conditions that generated tensile stress, followed by immersion in a potassium hydroxide solution. This figure demonstrates the formation of microdefects in which etch pits are arrayed along a microfissure. The rectangular outlines in FIG. 3 are markings provided in order to highlight the defects.

The generation of such microdefects can be inhibited by shifting from tensile internal stress to compressive stress. However, in the case of a bottom emission type device, when a passivation layer is formed on the OCL under conditions that generate compressive stress, there is a high likelihood that the glass substrate will warp and that a difference in height will occur between the middle of the glass substrate and its ends. This creates the risk that the organic layer cannot be formed with good precision during formation of the organic layer using, for example, a photolithographic process.

In addition, in the case of the top emission configuration, when the passivation layer is formed on the organic layer, the appearance of delamination is a risk when internal stress is present in the passivation layer due to the very weak adhesive strength with, for example, the underlying electrode of the organic layer. This makes it necessary to form the passivation layer under conditions that give low internal stress.

In order to obtain display devices that are provided with long-life organic EL devices in which the generation of dark spots and so forth in the organic layer is inhibited, there is a desire, in view of the circumstances described above, to reduce the microdefects in the passivation layer and thereby diminish the diffusion of moisture at the passivation layer. Technology in which a layer having compressive stress and a layer having tensile stress are stacked in alternation is known as a passivation layer film-formation technology that takes these considerations into account, and the following, for example, has been disclosed in this regard.

A method of forming a protective film is disclosed in Japanese Patent Application Laid-open No. 2004-063304. In this method, a protective film comprising a multilayer film of silicon nitride films is formed by high-density plasma CVD. By varying the nitrogen gas concentration in the film-formation precursor gas, a protective film is formed in which a silicon nitride film having compressive stress and a silicon nitride film having tensile stress are stacked in alternation.

An organic electroluminescent device is disclosed in Japanese Patent Application Laid-open No. 2005-222778 that has a hole injection electrode layer, an electron injection electrode layer, an organic layer sandwiched between the hole injection electrode layer and the electron injection electrode layer, and a protective film that coats the exposed surfaces of the electron injection electrode layer and the organic layer. This protective film is a multilayer film formed by stacking at least two layers, i.e., a silicon nitride layer having compressive stress and a silicon nitride layer having tensile stress.

The present invention is directed to overcoming or at least reducing the effects of one or more of the problems set forth above.

### SUMMARY OF THE INVENTION

In Japanese Patent Application Laid-open No. 2004-063304, the alternating stack of the layer having compressive stress and the layer having tensile stress is realized using a means that varies the nitrogen gas concentration. The cited stack of layers is realized in Japanese Patent Application Laid-open No. 2005-222778 using a means that varies the flow rates and flow rate ratios of H₂ gas, N₂ gas, and SiH₄ gas. Both of the means disclosed in Japanese Patent Application Laid-open No. 2004-063304 and Japanese Patent Application Laid-open No. 2005-222778 provide control of the internal stress by adjusting the density by varying the composition ratio of the starting materials, and of necessity must employ high-density silicon nitride. However, the transparency of silicon nitride varies with its composition ratio, and it really cannot be said that high-density, high refractive index silicon nitride, being somewhat yellow, has an excellent transparency.

An object of the present invention, therefore, is to provide a method of producing an organic EL device that is provided with a highly transparent passivation layer and that as a whole exhibits a high color reproducibility.

The present invention relates to a method of producing an organic EL device that is provided with a passivation layer wherein, during formation of the passivation layer by a CVD method, a layer in which the internal stress is compressive stress and a layer in which the internal stress is tensile stress are stacked by modulating a gas pressure while holding a gas composition ratio constant. The method of producing organic EL devices of the present invention can be used to produce display devices such as organic EL displays that exhibit a high color reproducibility.

The gas pressure in the method of producing organic EL devices of the present invention is desirably 25 to 75 Pa or 125 to 200 Pa. This production method also encompasses production of an internal stress-free layer during formation of the passivation layer stack by a CVD method, by modulating the gas pressure while holding the gas composition ratio constant. In this case, the gas pressure at the aforesaid gas composition ratio is desirably greater than 75 Pa but less than 125 Pa. The layer in which the internal stress is compressive stress, the layer in which the internal stress is tensile stress, and the layer that is internal stress free, can be formed in this production method from at least one selected from oxides, nitrides, and oxynitrides.

The method of producing organic EL devices of the present invention, through a novel means of exercising suitable control of the gas composition ratio and gas pressure, enables the use of a highly transparent constituent that was not heretofore possible and as a consequence makes possible a highly transparent passivation layer and thereby makes possible an excellent color reproducibility for the organic EL device.

### BRIEF DESCRIPTION OF THE DRAWINGS

The foregoing advantages and features of the invention will become apparent upon reference to the following detailed description and the accompanying drawings, of which:

FIG. 1 is a cross-sectional diagram that shows the sequence of the individual stages in the method of producing organic EL devices of the present invention in which FIG. 1A shows the stage of CCM layer formation, FIG. 1B shows the stage of overcoat layer formation, FIG. 1C shows the stage of passivation layer formation, FIG. 1D shows the stage of transparent anode formation, FIG. 1E shows the stage of organic layer formation, and FIG. 1F shows the stage of metal cathode formation;

FIG. 2 is a cross-sectional diagram that shows examples of the sealing structure for the organic EL device of the present invention, in which FIG. 2A shows an example that uses a sealing element and an adhesive layer as the sealing materials and FIG. 2B shows an example that uses a passivation film as the sealing material; and

FIG. 3 is a photograph that shows the results of the observation of the etch pits produced when a silicon nitride layer was formed as a passivation layer on a silicon wafer under conditions that generated tensile stress, followed by immersion in a potassium hydroxide solution.

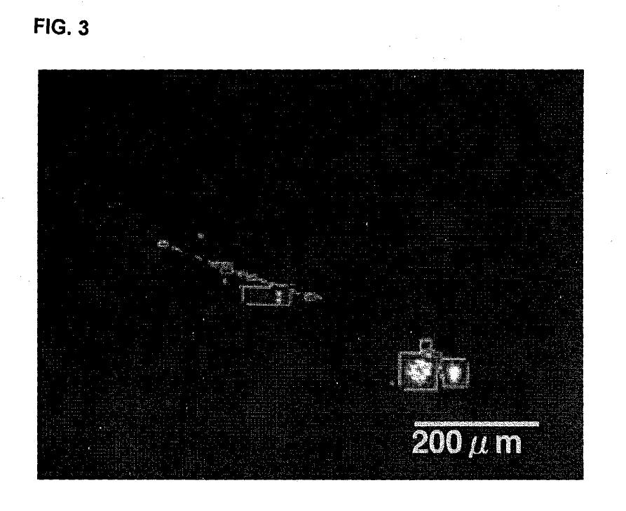

### DETAILED DESCRIPTION OF SPECIFIC EMBODIMENTS

Suitable embodiments of the present invention are described in the following with reference to the drawings. The examples provided below are nothing more than examples, and suitable design variations can be made within the scope of the ordinary creative capacity of the individual skilled in the art.

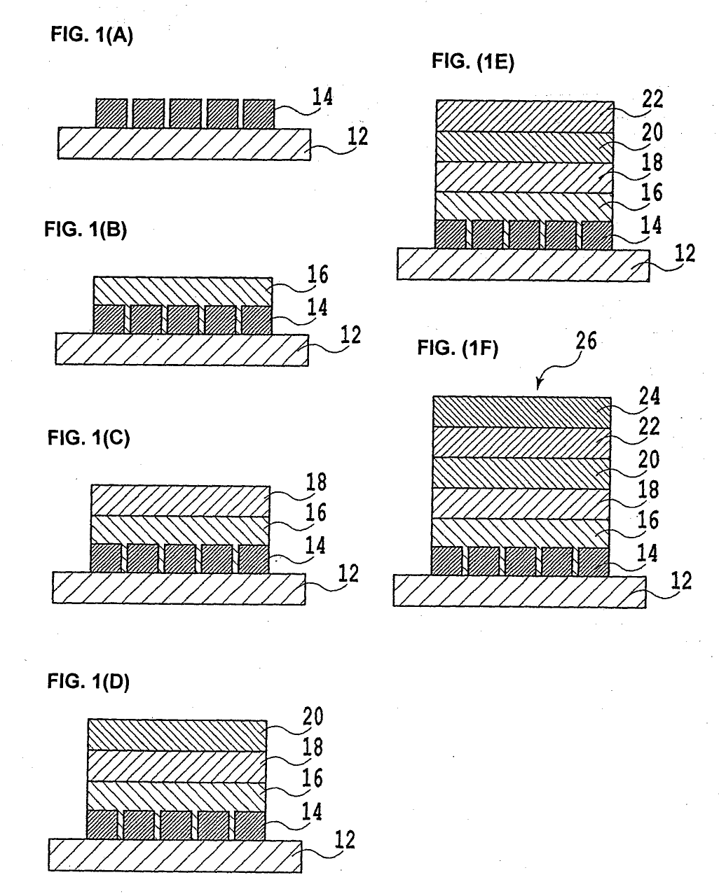

Cross-sectional drawings are given in FIG. 1 that show each stage in sequence in the method of producing an organic EL device of the present invention. While the example shown in FIG. 1 concerns the bottom emission configuration, the discussion of the stage of passivation layer production, which is the characteristic matter of the present invention, is also suitably supplemented as necessary with a discussion of the top emission configuration.

### Formation of CCM Layer 14

In the first stage, which is shown in FIG. 1A, CCM layer 14 is formed on substrate 12.

Substrate 12 is not particularly limited as long as it is capable of withstanding the various conditions (e.g., solvent, temperature, and so forth) encountered in the formation of the layers that will be sequentially layered thereon; however, an excellent dimensional stability is preferred. Examples of preferred substrates 12 are glass substrates and rigid plastic substrates formed, for example, of polyolefin, acrylic resin such as polymethyl methacrylate, polyester resin such as polyethylene terephthalate, polycarbonate resin, or polyimide resin. Other examples of preferred substrates 12 are flexible films formed, for example, of polyolefin, acrylic resin such as polymethyl methacrylate, polyester resin such as polyethylene terephthalate, polycarbonate resin, or polyimide resin.

CCM layer 14 is formed on substrate 12 in order to realize the ability to emit the three colors of red, green, and blue (also abbreviated below as RGB). CCM layer 14 can comprise a color conversion layer and/or a color filter layer.

The color conversion layer is a layer that contains a fluorescent dye for the purpose of color conversion, and it may also contain a matrix resin. It is a layer that alters the wavelength distribution of the light emitted from the organic device described below, in order to emit light in a different wavelength region. In the present case, the fluorescent dye comprising the color conversion layer is a dye that emits light in a desired wavelength region (for example, red, green, or blue).

Fluorescent dyes that absorb light in the blue to blue-green region and produce fluorescence in the red region can be exemplified by rhodamine dyes such as rhodamine B, rhodamine 6G, rhodamine 3B, rhodamine 101, rhodamine 110, sulforhodamine, basic violet 11, and basic red 2; cyanine dyes; pyridine dyes such as 1-ethyl-2-[4-(p-dimethylaminophenyl)-1,3-butadienyl]pyridinium perchlorate (pyridine 1); and oxazine dyes. Various other dyes (e.g., direct dyes, acid dyes, basic dyes, disperse dyes, and so forth) can also be used as long as they are fluorescent.

In contrast to the preceding, fluorescent dyes that absorb light in the blue to blue-green region and produce fluorescence in the green region can be exemplified by coumarin dyes such as 3-(2′-benzothiazolyl)-7-diethylaminocoumarin (coumarin 6), 3-(2′-benzoimidazolyl)-7-diethylaminocoumarin (coumarin 7), 3-(2′-N-methylbenzo-imidazolyl)-7-diethylaminocoumarin (coumarin 30), and 2,3,5,6-1H,4H-tetrahydro-8-trifluoromethylquinolidine(9,9a,1-gh)coumarin (coumarin 153); basic yellow 51, which is a dye in the coumarin dye class; and also naphthalimide dyes such as solvent yellow 11 and solvent yellow 116. Various other dyes (e.g., direct dyes, acid dyes, basic dyes, disperse dyes, and so forth) can also be used as long as they are fluorescent.

The matrix resin constituent of the color conversion layer can be an acrylic resin or any of various silicone polymers or any resin capable of being substituted for the preceding. For example, a silicone polymer as such or a resin-modified silicone polymer can be used.

The color filter layer is a layer that transmits only light of a desired wavelength region. The elaboration of the color filter layer in a layer structure with a color conversion layer is effective for increasing the color purity of the light that has undergone an alteration of its wavelength distribution by the color conversion layer. The color filter layer can be exemplified by color filter layers that use commercially available color filter materials for the liquid crystal sector, such as Color Mosaic from Fujifilm Electronic Materials Co., Ltd.

Various photoprocesses can be used to form CCM layer 14 (comprising a color conversion layer and/or a color filter layer) on the aforementioned substrate 12.

In order to efficiently convert the light from the organic layer described below, to each particular color, formation of CCM layer 14 must be executed in such a manner that the color conversion layer for each of the colors (RGB) reaches a thickness of about 5 μm. In addition, overlap between the individual color conversion layers must also be avoided in order to prevent color bleed. For example, in order to obtain a resolution of 70 dpi, the RGB subpixels must be arrayed with a spacing of 120 μm, and, in order to prevent color bleed, the individual RGB color conversion layers must be separated by approximately 10 μm. As a result, a trench with a width of 10 μm and a depth of 5 μm is formed between subpixels.

### Formation of Overcoat Layer 16

In the second stage, which is shown in FIG. 1B, overcoat layer 16 is formed on CCM layer 14 and in the trenches formed in between.

As noted above, a trench with a width of 10 μm and a depth of 5 μm is formed between subpixels. Since this trench quite substantially interferes with formation of the organic EL layer and interconnects, a preliminary planarization to bury this trench must be carried out prior to the sequential formation of a desired layer, e.g., passivation layer 18, on CCM layer 14.

For example, novolac resins and photocuring resins and/or thermosetting resins, e.g., imide-modified silicone resins, epoxy-modified acrylate resins, acrylate monomer/oligomer/polymer resin that contains reactive vinyl, and fluororesins, can be used as overcoat layer 16.

Spin coating and so forth can be used to form overcoat layer 16. For example, a film thickness of 1 to 5 μm can be applied by spin coating, followed by prebaking, exposure to light using a photomask that has open areas in prescribed locations, development, and baking. The resist residues on CCM layer 14 can be reduced at this point by using a novolac resin-type material as overcoat layer 16.

### Formation of Passivation Layer 18

In the third stage, which is shown in FIG. 1C, passivation layer 18 is formed on overcoat layer 16.

As noted above, the resist residue on CCM layer 14 can be reduced by using a novolac resin-type material as overcoat layer 16; however, the complete removal of this residue still is quite problematic. This creates the risk that the trace amounts of moisture present in this residue could diffuse into the organic layer described below, and cause a deterioration in luminance induced by the generation of dark spots and the like. Passivation layer 18 that functions to inhibit moisture diffusion into the organic layer is therefore disposed on overcoat layer 16.

Passivation layer 18 can be a highly moisture-impermeable material, for example, an insulating inorganic oxide, inorganic nitride, inorganic oxynitride, and so forth, such as SiOₓ, SiNₓ, SiNₓO_{y}, AlOₓ, TiOₓ, TaOₓ, ZnOₓ, and so forth.

Chemical vapor deposition (also abbreviated below as CVD) can be used to form passivation layer 18. The use of plasma CVD is particularly preferred for its ability to carry out formation at low temperatures.

When such a CVD method is employed, an organic silane or an inorganic silane such as monosilane or disilane can be used as the silicon source gas. N₂O can be used as the oxygen source gas. Ammonia, nitrogen gas, or their mixture can be used as the nitrogen source gas.

One characterizing feature of the present invention, i.e., that the “gas composition ratio is held constant during formation of passivation layer 18”, is essential for the formation of passivation layer 18. Taking, as an example, the use of SiN film for passivation layer 18 after the sequential formation of films 14 and 16 on glass substrate 12 having dimensions of 370 mm×470 mm, the gas composition ratio is preferably held constant at SiH₄ (silane gas):NH₃:N₂=1:2:20.

While operating under this condition of a constant gas composition ratio, the silane gas flow rate is preferably 150 sccm. Moreover, the range of 200 to 400 sccm NH₃ gas per 150 sccm silane gas is additionally preferred, while the range of 250 to 350 sccm NH₃ gas per 150 sccm silane gas is highly preferred. When the NH₃ gas is greater than or equal to this 200 sccm, the SiN film is not discolored and an excellent transparency can be realized. An excellent passivity can be realized when, on the other hand, the NH₃ gas does not exceed the 400 sccm cited above.

The range of 1000 to 5000 sccm N₂ gas per 150 sccm silane gas is additionally preferred, while the range of 2000 to 4000 sccm N₂ gas per 150 sccm silane gas is highly preferred. N₂ gas exhibits the same tendencies as cited above for NH₃ gas. That is, when the N₂ gas is greater than or equal to 1000 sccm, the SiN film is not discolored and an excellent transparency can be realized while an excellent passivity can be realized when the N₂ gas does not exceed the 5000 sccm cited above.

When SiN film (passivation layer 18) is formed at such a gas composition ratio and in the preferred flow rate range for each gas, transparency can be achieved for passivation layer 18 in the visible region in the wavelength range of 400 to 800 nm. For formation in the preferred ranges cited above, the extinction coefficient for light in passivation layer 18 can be brought to 0.001 or less and the absorption of light in passivation layer 18 (SiN layer) with a thickness of 400 nm can be brought to 1% or less. At film formation conditions designated as the reference film formation conditions (150 sccm silane gas, 300 sccm NH₃ gas, and 3 sLm N₂ gas), the extinction coefficient for light in passivation layer 18 can be brought to 0.0001 or less and the absorption of light in passivation layer 18 (SiN layer) with a thickness of 400 nm can be brought to 0.1% or less.

While it is essential that the gas composition ratio during formation of passivation layer 18 be held constant, a further characterizing feature of the present invention, that of “modulation of the gas pressure during formation,” also is essential during the formation of passivation layer 18. This gas pressure modulation can be carried out by controlling the pressure of the gas used by adjusting the aperture of a gate valve that is disposed between a vacuum pump and the chamber where passivation layer 18 layer is formed.

For example, the pressure is preferably modulated by selecting the range of 25 to 75 Pa in alternation with the range of 125 to 200 Pa. By doing this, a layer in which the internal stress is compressive stress (also abbreviated hereafter as the compressive stress layer) and a layer in which the internal stress is tensile stress (also abbreviated hereafter as the tensile stress layer) are stacked in alternation using the CVD method and passivation layer 18 as a whole can be brought into a state in which the internal stress is not biased to either tensile stress or compressive stress. As a consequence, point defects such as microfissures and the like are not produced in passivation layer 18; the migration of moisture to the organic layer through these fissures is thereby inhibited; and the generation of dark spots and the like at the organic layer can be prevented as a result.

The stack of passivation layer 18 is preferably carried out so as to bring the internal stress for passivation layer 18 as a whole into the range of −50 MPa (compressive stress) to +50 MPa (tensile stress). This is done in order to avoid the production of a bias in the internal stress for the laminate as a whole and thereby avoid the production of point defects within passivation layer 18. More specifically, for the layers constituting passivation layer 18, bringing the internal stress of the compressive stress layers into the range of −150 MPa to −50 MPa is preferred from the perspective of restraining substrate warp. Similarly, for the layers constituting passivation layer 18, bringing the internal stress of the tensile stress layers into the range from +50 MPa to +150 MPa is preferred from the perspective of restraining substrate warp and from the perspective of inhibiting fissure generation within the passivation layer.

In the case of the bottom emission-type device shown in FIG. 1, the internal stress of the laminate constituting passivation layer 18 may assume somewhat elevated values during stacking in the formation of passivation layer 18 on overcoat layer 16. This is due to the excellent adhesion to the substrate and the excellent mutual adhesion of the color filter layer, CCM, overcoat layer, and so forth, fabricated before the passivation layer step.

In contrast to the preceding, in a top emission-type device (not shown), on the occasion of the formation of the passivation layer on the organic layer, the internal stress of the aforementioned laminate during this formation must be in the range of −50 MPa (compressive stress) to +50 MPa (tensile stress). This is because the debonding stress limit for this laminate is ±50 MPa.

The internal stress variation regime for such a laminate, considered for the stack of a plurality of 200 nm-thick layers, can be, for example, a regime in which the first layer is a stress-free layer and in which, for the second and subsequent layers, a −100 MPa compressive stress layer and a +100 MPa tensile stress layer are stacked in alternation. According to this regime, when an even number of layers (the second layer, fourth layer, and so forth) have been stacked beginning with the second layer, a compressive stress of no more than −50 MPa exists for the laminate as a whole, and when an odd number of layers have been stacked, internal stress is not present for the laminate as a whole. That is, when this internal stress variation regime is employed, the debonding stress limit of ±50 MPa for the laminate is not exceeded and unification of the laminate can be satisfactorily realized.

The aforementioned internal stress has the following behavior: when a low gas pressure is used during the formation of a particular layer constituting passivation layer 18, the internal stress will be compressive stress for that particular layer; when a high gas pressure is used, the internal stress will be tensile stress for that layer. Specifically, when the gas pressure during formation is from a value in excess of 75 Pa to less than 125 Pa, that layer will be a stress-free layer, while a compressive stress layer is formed at a gas pressure lower than the gas pressure of this range and a tensile stress layer is formed at a higher gas pressure.

With regard to the control of this gas pressure, the gas pressure for the formation of a stress-free layer is preferably in the range of 90 to 110 Pa. Compressive stress is completely absent at a gas pressure of 90 Pa or greater, while tensile stress is completely absent at a gas pressure of 110 Pa or less.

The gas pressure must be in the range of 25 to 75 Pa to form a compressive stress layer, while the range of 40 to 60 Pa is preferred. At a gas pressure of 25 Pa or more, there is little possibility that the stress of the laminate as a whole will exceed −50 MPa. The effect of a complete absence of risk that the stress of the laminate as a whole will exceed −50 MPa is strongly achieved when the gas pressure is 40 Pa or more. Compressive stress can be very reliably realized for the internal stress when the gas pressure is 60 Pa or less.

Furthermore, the gas pressure must be in the range of 125 to 200 Pa to form a tensile stress layer, while the range of 130 to 170 Pa is preferred. At a gas pressure of 200 Pa or less, there is little possibility that the stress of the laminate as a whole will exceed +50 MPa. The effect of a complete absence of risk that the stress of the laminate as a whole will exceed +50 MPa is strongly achieved when the gas pressure is 170 Pa or less. Tensile stress can be very reliably realized for the internal stress when the gas pressure is at least 130 Pa.

In the case of the bottom emission-type device shown in FIG. 1, this passivation layer 18 is preferably formed in a thickness of 100 nm to 1 μm in order to inhibit moisture absorption and ensure adherence with overcoat layer 16. In contrast to this, in the case of a top emission-type device (not shown), this passivation layer 18 is preferably formed in a thickness of 1 to 5 μm based on a consideration of stopping the infiltration of water vapor from the atmosphere with only the passivation layer.

In the case of the bottom emission-type device shown in FIG. 1, this passivation layer 18 is preferably formed using a substrate 12 temperature of no more than 220° C. in order to inhibit heat-induced damage to CCM layer 14 formed on substrate 12. In contrast to this, in the case of a top emission-type device (not shown), the passivation layer 18 is formed on the organic layer, so it preferably is formed at conditions not exceeding 100° C. in order to inhibit degradation of the organic layer.

### Formation of Transparent Anode 20, Organic Layer 22, and Metal Cathode 24

An organic light emitter is formed on substrate 12, CCM layer 14, overcoat layer 16, and passivation layer 18 which have been formed in sequence as described above. The organic light emitter contains a pair of electrodes and, as shown in FIG. 1, has transparent anode 20 as a lower electrode and metal cathode 24 as an upper electrode and has organic layer 22 formed between the two electrodes. Organic layer 22 has a structure that contains an organic EL layer with, for example, a hole injection layer, electron injection layer, and so forth, interposed on an optional basis.

Any of the layer structures shown below can be used as the organic light emitter, as shown in FIG. 1:

(1) transparent anode 20/organic EL layer/metal cathode 24

(2) transparent anode 20/hole injection layer/organic EL layer/metal cathode 24

(3) transparent anode 20/organic EL layer/electron injection layer/metal cathode 24

(4) transparent anode 20/hole injection layer/organic EL layer/electron injection layer/metal cathode 24

(5) transparent anode 20/hole injection layer/hole transport layer/organic EL layer/electron injection layer/metal cathode 24

(6) transparent anode 20/hole injection layer/hole transport layer/organic EL layer/electron transport layer/electron injection layer/metal cathode 24

### Formation of Transparent Anode 20

In the fourth stage, which is shown in FIG. 1D, transparent anode 20 is formed on passivation layer 18.

Transparent oxide materials can be used as transparent anode 20. The use of IZO is preferred from the standpoint of the planarity of the film-formation surface. In addition, transparent anode 20 can be formed using any means known in the pertinent art, such as vapor deposition (resistance heating or electron beam heating).

### Formation of Organic Layer 22

In the fifth stage, which is shown in FIG. 1E, organic layer 22 is formed on transparent anode 20. Organic layer 22 contains an organic EL layer and may optionally contain a hole injection layer, electron injection layer, and so forth.

The material of the organic EL layer can be selected in correspondence to the desired color. For example, in order to obtain the emission of blue to blue-green light, at least 1 substance can be used from fluorescent brightening agents (e.g., benzothiazole types, benzoimidazole types, benzooxazole types, and so forth), styrylbenzene-type compounds, and aromatic dimethylidine-type compounds. Or, the organic EL layer may be formed by using the preceding substances as a host material and adding a dopant thereto. Substances usable as this dopant include, for example, perylene (blue), which is known for use as a laser dye.

Phthalocyanines (Pc) (including, for example, copper phthalocyanine (CuPc)), indanthrene-type compounds, and so forth, can be used as the material of the hole injection layer.

Substances having a structure with a triarylamine moiety, carbazole moiety, or oxadiazole moiety (for example, TPD, α-NPD, PBD, m-MTDATA, and so forth) can be used as the material of the hole transport layer.

Aluminum complexes such as aluminum tris(8-quinolinolate) (Alq₃), aluminum complexes doped with an alkali metal or alkaline-earth metal, or bathophenanthroline containing an alkali metal or alkaline-earth metal can be used as the material of the electron injection layer.

Substances such as aluminum complexes such as Alq₃, oxadiazole derivatives such as PBD and TPOB, triazole derivatives such as TAZ, triazine derivatives, phenylquinoxalines, thiophene derivatives such as BMB-2T, and so forth can be used as the material of the electron transport layer.

Each layer making up organic layer 22 can be formed using any means known in the pertinent art, such as vapor deposition (resistance heating or electron beam heating).

### Formation of Metal Cathode 24

In the sixth stage, which is shown in FIG. 1F, metal cathode 24 is formed on organic layer 22.

The material of metal cathode 24 is not particularly limited as long as it has a low resistance and is corrosion resistant; however, the use of metals such as Ni alloys, Cr alloys, Cu alloys, Al alloys, Mo, and so forth, is preferred. Metal cathode 24 can be formed using any means known in the pertinent art, such as vapor deposition (resistance heating or electron beam heating).

### Sealing the Organic EL Device

Traversing the individual stages described above yields organic EL device 26 comprising, as shown in FIG. 1F, CCM layer 14, overcoat layer 16, passivation layer 18, transparent anode 20, organic layer 22, and metal cathode 24 on substrate 12. However, while in this state, there is a risk of moisture infiltrating from the outside into organic layer 22 and causing deterioration in organic layer 22 and so forth. It therefore becomes necessary to seal organic EL device 26 by some means.

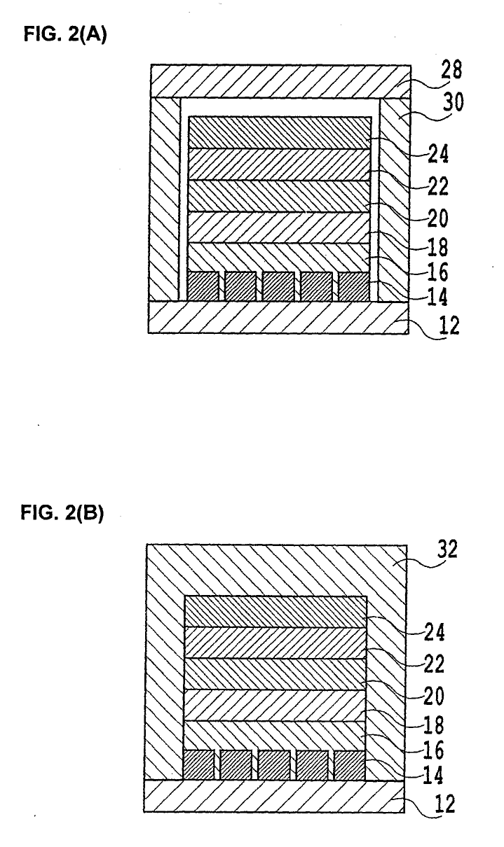

FIG. 2 is a cross-sectional diagram that shows examples of sealing structures for the organic EL device of the present invention. An example is shown in FIG. 2A in which sealing element 28 and adhesive layer 30 are used as the sealing materials, while an example is shown in FIG. 2B in which passivation film 32 is used as the sealing material.

Considering the example shown in FIG. 2A, a glass substrate can be used as sealing element 28 and a UV-curing adhesive can be used as adhesive layer 30. The sealing structure example shown in FIG. 2A is obtained by bonding the glass substrate to the organic EL device, for example, under a dry nitrogen atmosphere in a glove box. The oxygen concentration in the atmosphere is no more than 10 ppm and the moisture concentration in the atmosphere is also no more than 10 ppm under preferred sealing conditions.

The same scheme, e.g., the materials used, the method of formation, and so forth, as discussed with reference to passivation layer 18 can be used as the scheme for forming passivation layer 32 to obtain the sealing structure shown in FIG. 2B.

By holding the gas composition ratio constant during formation of passivation layer 18, the method of producing an organic EL device of the present invention as described hereinabove makes it possible to obtain an excellent transparency and passivity for passivation layer 18 and also makes it possible to obtain an excellent extinction coefficient in passivation layer 18. In addition, a plurality of layers comprising compressive stress and tensile stress layers can be formed by modulating the gas pressure during formation of passivation layer 18 in accordance with the production method under consideration, which makes it possible to prevent microdefects within layer 18 and to prevent the generation of point defects, such as dark spots and so forth, in organic layer 22. Accordingly, these effects combine in the production method under consideration to enable the realization of an excellent color reproducibility for the organic EL device.

The examples given above have related primarily to the production of bottom emission-type devices. However, as noted to some extent above, holding the gas composition ratio constant during formation of passivation layer 18 and modulating the gas pressure during formation can also be applied to top emission-type devices, whereby the same effects are obtained as for bottom emission-type devices.

### EXAMPLES

The present invention is described in detail through the following examples in order to provide an actual demonstration of the effects of the present invention.

Organic EL Device with the Sealing Structure Shown in FIG. 2A

### Example 1

An organic EL device having the sealing structure shown in FIG. 2A was fabricated. A color filter layer and CCM layer (R, G, B) were first formed on a glass substrate (1737 glass from Corning) by spin coating and photolithography, and an overcoat layer (epoxy-modified acrylate resin) was formed on the CCM layer by spin coating and photolithography.

A passivation layer was then obtained by forming SiNₓ in a total thickness of 400 nm by plasma CVD while maintaining the substrate temperature at 130° C. The gas composition during formation of the passivation layer corresponded to a gas composition ratio of SiH₄:NH₃:N₂=1:2:20 for 150 sccm SiH₄, and the gas composition ratio was held constant during formation.

Modulation of the gas pressure during passivation layer formation was controlled by adjusting the aperture of a gate valve provided between the production chamber and the vacuum pump. In preliminary investigations of film formation, the internal stress of the individual layers making up the passivation layer was 0 for a gas pressure of 100 Pa. The internal stress of the individual layers making up the passivation layer was −100 MPa (compressive stress) at a gas pressure of 50 Pa. The internal stress of the individual layers making up the passivation layer was +100 (tensile stress) at a gas pressure of 150 Pa. Based on these results, the gas pressure was first adjusted to 150 Pa and a 100 nm first layer constituting a tensile stress layer (+100 MPa) was formed. The gas pressure was then adjusted to 50 Pa and a 200 nm second layer constituting a compressive stress layer (−100 MPa) was formed. The gas pressure was further adjusted to 150 Pa and a 100 nm third layer constituting a tensile stress layer (+100 MPa) was formed, thus yielding the passivation layer. The extinction coefficient of the SiN layer formed in this manner was no more than 0.0001 according to ellipsometric measurement.

A transparent anode comprising IZO was formed by sputtering on the passivation layer to serve as the lower electrode.

An organic layer (hole injection layer, hole transport layer, organic EL layer, electron transport layer) was then formed on the transparent anode by vapor deposition with resistance heating. For the hole injection layer, a 100-nm layer was formed of copper phthalocyanine (CuPc) doped with 2 vol % acceptor (F4-TCNQ). A 20-nm layer of 4,4′-bis[N-(1-naphthyl)-N-phenylamino]biphenyl (α-NPD) was formed for the hole transport layer. A 30-nm layer of 4,4′-bis(2,2′-diphenylvinyl)biphenyl (DPVBi) was formed for the organic EL layer. A 20-nm layer of an aluminum chelate (Alq₃) was formed for the electron transport layer.

A metal cathode comprising 0.5 nm-thick LiF and 200 nm-thick Al was formed as the upper electrode on the organic layer by vapor deposition with resistance heating. This metal cathode was formed using a mask that yielded a stripe pattern of 2 nm lines with a 0.5 nm pitch that was orthogonal to the lines of the transparent anode cited above.

Finally, the organic EL device was sealed under a dry nitrogen atmosphere in a glove box (oxygen concentration no more than 10 ppm, moisture concentration no more than 10 ppm) using a glass substrate and a UV-curing adhesive to give the sealing structure shown in FIG. 2A.

### Comparative Example 1

An organic EL device with the sealing structure shown in FIG. 2A was obtained using the same conditions as in Example 1, with the exception that a 400-nm stress-free layer of SiNₓ was formed by using a gas pressure of 100 Pa during passivation film formation.

The reliability of each of the devices obtained in Example 1 and Comparative Example 1 was evaluated. Specifically, each device was subjected to high-temperature life testing under power for 1000 hours at 80° C. and 150 cd/cm², after which the number of dark spots in a randomly selected 100 cm² region of the organic layer was investigated; this number was collected from 300 pixel sets and its average was calculated. The results are shown in Table 1, and show that dark spot generation could be inhibited in Example 1 in comparison to Comparative Example 1.

TABLE 1

| | average number of dark spots |
|---|---|
| | (number/100 cm2) |
| Example 1 | 0.01 |
| Comparative Example 1 | 2.0 |

Organic EL Device with the Sealing Structure Shown in FIG. 2B

### Example 2

An organic EL device having the sealing structure shown in FIG. 2B was fabricated. A color filter layer and CCM layer (R, G, B) were first formed on a glass substrate (1737 glass from Corning) by spin coating and photolithography, and an overcoat layer (epoxy-modified acrylate resin) was formed on the CCM layer by spin coating and photolithography.

A passivation layer was then obtained by forming SiNₓ in a total thickness of 5 μm by plasma CVD while maintaining the substrate temperature at 60° C.

The gas composition during formation of the passivation layer corresponded to a gas composition ratio of SiH₄:NH₃:N₂=1:1:15 for 150 sccm SiH₄, and the gas composition ratio was held constant during formation.

Modulation of the gas pressure during passivation layer formation was controlled by adjusting the aperture of a gate valve provided between the formation chamber and the vacuum pump. The gas pressure was first adjusted to 100 Pa and a 200 nm first layer constituting a stress-free layer (0 MPa) was formed. The gas pressure was then adjusted to 150 Pa and a 100 nm second layer constituting a tensile stress layer (+100 MPa) was formed. The gas pressure was further adjusted to 50 Pa and a 200 nm third layer constituting a compressive stress layer (−100 MPa) was formed. A 200-nm tensile stress layer (+100 MPa) and a 200-nm compressive stress layer (−100 MPa) were thereafter formed in alternation to yield a passivation layer with an overall thickness of 5 μm. The extinction coefficient of the SiN layer formed in this manner was no more than 0.0001 according to ellipsometric measurement.

A transparent anode comprising IZO was formed by sputtering on the passivation layer to serve as the lower electrode.

An organic layer (hole injection layer, hole transport layer, organic EL layer, electron transport layer) was then formed on the transparent anode by vapor deposition with resistance heating. For the hole injection layer, a 100-nm layer was formed of copper phthalocyanine (CuPc) doped with 2 vol % acceptor (F4-TCNQ). A 20-nm layer of 4,4′-bis[N-(1-naphthyl)-N-phenylamino]biphenyl (α-NPD) was formed for the hole transport layer. A 30-nm layer of 4,4′-bis(2,2′-diphenylvinyl)biphenyl (DPVBi) was formed for the organic EL layer. A 20-nm layer of an aluminum chelate (Alq₃) was formed for the electron transport layer.

A metal cathode comprising 0.5 nm-thick LiF and 200 nm-thick Al was formed as the upper electrode on the organic layer by vapor deposition with resistance heating. This metal cathode was formed using a mask that yielded a stripe pattern of 2 nm lines with a 0.5 nm pitch that was orthogonal to the lines of the transparent anode cited above.

Finally, the organic EL device was sealed by forming SiN as the passivation layer by plasma CVD to give the sealing structure shown in FIG. 2B.

### Comparative Example 2

An organic EL device with the sealing structure shown in FIG. 2B was obtained using the same conditions as in Example 2, with the exception that a 5 μm stress-free layer of SiNₓ was formed by using a gas pressure of 100 Pa during passivation film formation.

The reliability of each of the devices obtained in Example 2 and Comparative Example 2 was evaluated. Specifically, each device was subjected to high-temperature life testing under power for 1000 hours at 80° C. and 150 cd/cm², after which the number of dark spots in a randomly selected 100 cm² region of the organic layer was investigated; this number was collected from 300 pixel sets and its average was calculated. The results are shown in Table 1, and show that dark spot generation could be inhibited in Example 2 in comparison to Comparative Example 2.

TABLE 2

| | average number of dark spots |
|---|---|
| | (number/100 cm2) |
| Example 2 | 0.01 |
| Comparative Example 2 | 10.0 |

The present invention, through the exercise of suitable control of the gas composition ratio and gas pressure during formation of the passivation layer, not only is able to provide a passivation layer with an excellent transparency, excellent passivity, excellent extinction ratio, and so forth, but also is able to inhibit microdefects in the passivation layer and thereby inhibit the generation of dark spots in the organic layer. Due to this, an excellent color reproducibility can be realized by organic EL devices obtained by the production method of the present invention. The present invention is therefore promising with regard to enabling the production of organic EL devices that can be used in various display devices for which there has in recent years been increasing demand for excellent color reproducibility.

Thus, a method of producing an organic EL device has been described according to the present invention. Many modifications and variations may be made to the techniques and structures described and illustrated herein without departing from the spirit and scope of the invention. Accordingly, it should be understood that the methods described herein are illustrative only and are not limiting upon the scope of the invention.

What is claimed is:

1. A method of producing an organic EL device that is provided with a passivation layer, wherein during formation of the passivation layer by a CVD method, a layer in which the internal stress is compressive stress and a layer in which the internal stress is tensile stress are stacked by modulating a gas pressure while holding a gas composition ratio constant.

2. The method of producing an organic EL device according to claim 1, wherein the gas pressure is modulated by alternating a pressure in the range of 25 to 75 Pa with a pressure in the range of 125 to 200 Pa.

3. The method of producing an organic EL device according to claim 1, wherein during formation of the passivation layer by the CVD method, a layer that is internal stress free is additionally stacked by modulating the gas pressure while holding the gas composition ratio constant.

4. The method of producing an organic EL device according to claim 2, wherein during formation of the passivation layer by the CVD method, a layer that is internal stress free is additionally stacked by modulating the gas pressure while holding the gas composition ratio constant.

5. The method of producing an organic EL device according to claim 3, wherein gas pressure is modulated in the range of 75 to 125 Pa during formation of the layer that is internal stress free.

6. The method of producing an organic EL device according to claim 4, wherein gas pressure is modulated in the range of 75 to 125 Pa during formation of the layer that is internal stress free.

7. The method of producing an organic EL device according to claim 1, wherein the stacked layers of the passivation layer are formed from at least one material selected from the group consisting of oxides, nitrides, and oxynitrides.

8. The method of producing an organic EL device according to claim 3, wherein the stacked layers of the passivation layer are formed from at least one material selected from the group consisting of oxides, nitrides, and oxynitrides.
